(19) United States
(12) Patent Application Publication
(10) Pub. No.: US 2026/0247993 A1
(43) Pub. Date: Aug. 20, 2026

(54) SEMICONDUCTOR WAFER

(71) Applicant: Kioxia Corporation, Tokyo (JP)

(72) Inventors: Keiko KANEDA, Chiba Chiba (JP); Takao SUEYAMA, Yokohama Kanagawa (JP); Michiko TSUMURA, Shinagawa Tokyo (JP)

(21) Appl. No.: 19/327,819

(22) Filed: Sep. 12, 2025

(30) Foreign Application Priority Data
Feb. 20, 2025 (JP) 2025-025785

(51) Int. Cl. H10W 70/40; G01R 31/28; H10W 90/00

(52) U.S. Cl. CPC H10W 70/421; G01R 31/2831; H10W 90/811

(57) ABSTRACT

A semiconductor wafer includes test-subject pattern lines including a first test-subject insulating film and including first test-subject lines and second test-subject lines that are alternately disposed on the first test-subject insulating film to be electrically insulated from each other. A first lead-out line is electrically connected to the first test-subject lines and has a larger width than the first and second test-subject lines. A second lead-out line is electrically connected to the second test-subject lines and has a larger width than the first and second test-subject lines. A third lead-out line is electrically connected to the second lead-out line, and includes first and second sections, each having a larger width than the first and second test-subject lines, and an intermediate section that is between the first and second sections and has a smaller width than the first and second section.

### CROSS-REFERENCE TO RELATED APPLICATIONS

This application is based upon and claims the benefit of priority from Japanese Patent Application No. 2025-025785, filed February 20, 2025, the entire contents of which are incorporated herein by reference.

### FIELD

Embodiments described herein relate generally to a semiconductor wafer.

### BACKGROUND

In a semiconductor test such as time dependent dielectric breakdown (TDDB), when a high voltage is applied between lines of a test-subject device, a short circuit may occur between the lines, causing high current to flow. In such a case, the current may cause probes of a probe card to melt, which could require a repair of the probe card. In addition, a lead-out line of the test-subject device may be broken, making it impossible to accurately measure a value of current flowing between the lines after the test.

### BRIEF DESCRIPTION OF THE DRAWINGS

FIG. 1 is a plan view illustrating a configuration example of a semiconductor wafer according to a first embodiment.

FIG. 2 is a plan view illustrating a configuration example of test-subject pattern lines and the vicinity thereof according to the first embodiment.

FIG. 3 is a plan view illustrating a configuration example of a lead-out line.

FIG. 4 is a plan view illustrating a configuration example of test-subject pattern lines and the vicinity thereof according to a second embodiment.

### DETAILED DESCRIPTION

Embodiments provide a semiconductor wafer having test-subject pattern lines that is capable of preventing damage to probes in a semiconductor test, and enables accurate measurement of a value of current flowing between the test-pattern lines after the test.

In general, according to one embodiment, a semiconductor wafer includes test-subject pattern lines including a first test-subject insulating film and including first test-subject lines and second test-subject lines that are alternately disposed on the first test-subject insulating film to be electrically insulated from each other. A first lead-out line is electrically connected to the first test-subject lines and has a larger width than the first and second test-subject lines. A second lead-out line is electrically connected to the second test-subject lines and has a larger width than the first and second test-subject lines. A third lead-out line is electrically connected to the second lead-out line, and includes first and second sections, each having a larger width than the first and second test-subject lines, and an intermediate section that is between the first and second sections and has a smaller width than the third lead-out line.

Embodiments according to the present invention will be described below with reference to the drawings. The present embodiments are not intended to limit the scope of the present invention. The drawings are schematic or conceptual. In the description and drawings, the same components are denoted by the same reference characters.

### First Embodiment

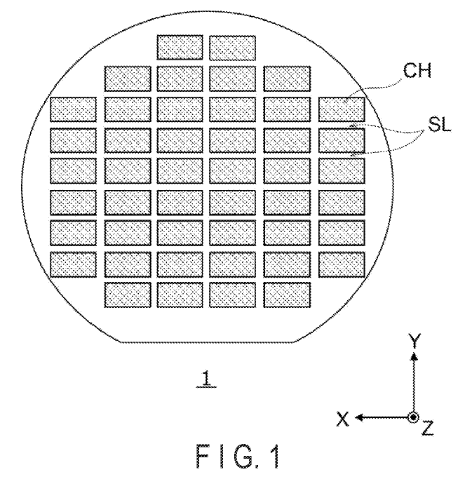

FIG. 1 is a plan view illustrating a configuration example of a semiconductor wafer according to a first embodiment.

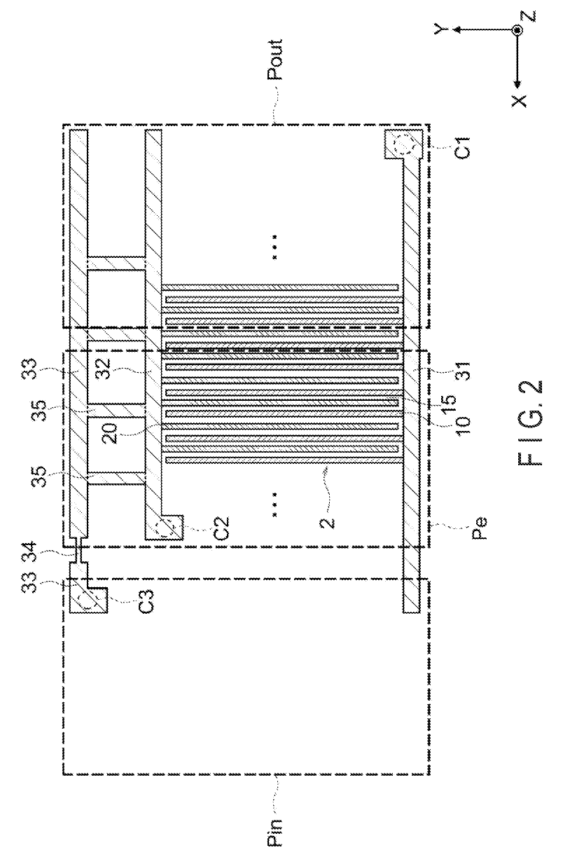

A semiconductor wafer 1 includes a plurality of semiconductor chips CH and scribe lines SL that are present between adjacent semiconductor chips CH. On each of the semiconductor chips CH, semiconductor elements such as transistors, which are not illustrated, are formed. The scribe lines SL are regions that are to be cut when the plurality of semiconductor chips CH are diced in a dicing step. Test-subject pattern lines 2, lead-out lines 31 to 35, and pads Pin and Pout in FIG. 2 are provided in the scribe lines SL in FIG. 1. Therefore, when the semiconductor wafer 1 is diced in the dicing step, the test-subject pattern lines 2 and the like are cut. Note that, in some embodiments, the test-subject pattern lines 2, the lead-out lines 31 to 35, and the pads Pin and Pout in FIG. 2 may be provided in a space in each semiconductor chip CH in FIG. 1. In such embodiments, the test-subject pattern lines 2 and the like are left in each semiconductor chip CH.

FIG. 2 is a plan view illustrating a configuration example of the test-subject pattern lines and the vicinity thereof according to the first embodiment.

The semiconductor wafer 1 according to the present embodiment includes the test-subject pattern lines 2, the lead-out lines 31 to 35, contacts C1 to C3, and pads Pin, Pout, and Pe.

The test-subject pattern lines 2 include lines for testing that are provided for testing and measuring a breakdown voltage between lines. The test-subject pattern lines 2 are provided separately from lines provided in each semiconductor chip CH to function as a product. The test-subject pattern lines 2 include a plurality of test-subject lines 10, a plurality of test-subject lines 20, and a test-subject insulating film 15. The plurality of test-subject lines 10 and the plurality of test-subject lines 20 are alternately disposed across the test-subject insulating film 15 and are electrically insulated from each other by the test-subject insulating film 15. The test-subject lines 10 and 20 are embedded in the test-subject insulating film 15. For the test-subject lines 10 and 20, for example, a conductive material such as copper, tungsten, or aluminum is used. For the test-subject insulating film 15, for example, an insulating material such as a silicon oxide or a silicon nitride is used.

The plurality of test-subject lines 10 are all connected to the lead-out line 31, which is one of the lead-out lines. The plurality of test-subject lines 10 extend in a +Y direction from the lead-out line 31 toward the lead-out line 32 and are arranged in parallel in an X direction, which intersects with (e.g., is orthogonal to) a Y direction. The plurality of test-subject lines 10 do not reach the lead-out line 32 and are electrically isolated from the lead-out line 32 and the test-subject lines 20.

The plurality of test-subject lines 20 are all connected to the lead-out line 32, which is one of the lead-out lines. The plurality of test-subject lines 20 extend in a -Y direction from the lead-out line 32 toward the lead-out line 31 and are arranged in parallel in the X direction. The plurality of test-subject lines 20 do not reach the lead-out line 31 and are electrically isolated from the lead-out line 31 and the test-subject lines 10.

In this manner, the test-subject lines 10 and 20 are alternately arranged in the X direction in a staggered manner. Conforming to such a planar layout of the test-subject lines 10 and 20, the test-subject insulating film 15 is provided in a zigzag pattern between the test-subject lines 10 and the test-subject lines 20 in a plan view seen from a Z direction.

The lead-out line 31 extends in the X direction and is electrically connected to the plurality of test-subject lines 10. The lead-out line 31 is connected to the contact C1 at one end of the lead-out line 31. Via the contact C1, the lead-out line 31 is electrically connected to the pad Pout above (in a +Z direction) the lead-out line 31. The width of the lead-out line 31 is larger than the widths of the test-subject lines 10 and 20.

Here, the width of a line refers to a length of the line in a direction orthogonal to a direction of extension (referred to herein as longitudinal direction) of the line. For example, the widths of the lead-out lines 31 to 34 are their lengths in the Y direction. The widths of the test-subject lines 10 and 20 and the lead-out lines 35 are their lengths in the X direction.

The lead-out line 32 extends in the X direction and is electrically connected to the plurality of test-subject lines 20. The lead-out line 32 is connected to the contact C2 at one end of the lead-out line 32. Via the contact C2, the lead-out line 32 is electrically connected to the pad Pe above (in the +Z direction) the lead-out line 32. The width of the lead-out line 32 is larger than the widths of the test-subject lines 10 and 20. The width of the lead-out line 32 may be the same as the width of the lead-out line 31.

The lead-out line 33 extends in the X direction and is electrically connected to the lead-out line 32 via the lead-out lines 35. Therefore, the lead-out line 33 is electrically connected to all of the plurality of test-subject lines 20 via the lead-out lines 32 and 35. The lead-out line 33 is connected to the contact C3 at one end of the lead-out line 33. Via the contact C3, the lead-out line 33 is electrically connected to the pad Pin above (in the +Z direction) the lead-out line 33. The width of the lead-out line 33 is larger than the widths of the test-subject lines 10 and 20. The width of the lead-out line 33 may be the same as the widths of the lead-out lines 31 and 32.

The lead-out line 34 is provided at an intermediate point of the lead-out line 33. The lead-out line 34 is narrower (thinner) in width than the lead-out line 33, forming a neck. As with the lead-out line 33, the lead-out line 34 is electrically connected to all of the plurality of test-subject lines 20 via the lead-out lines 32 and 35. The lead-out line 34 is also connected to the contact C3. Therefore, the lead-out line 34 may be regarded as a part of the lead-out line 33.

The width of the lead-out line 34 is 1/3 or less than the width of the lead-out line 33. In addition, the width of the lead-out line 34 is smaller than the widths of the test-subject lines 10 and 20. In a breakdown test step (e.g., TDDB test), this configuration makes the lead-out line 34 function as a fuse when a short circuit occurs between one or more of the test-subject lines 10 and one or more of the test-subject lines 20 due to a breakdown between the one or more of the test-subject lines 10 and the one or more of the test-subject lines 20. That is, when the short circuit between the one or more of the test-subject lines 10 and the one or more of the test-subject lines 20 causes a relatively high current to flow, the current causes the lead-out line 34 to melt and break at an intermediate point of the lead-out line 33, thus electrically isolating the pad Pin and the test-subject pattern lines 2 from each other. It is thus possible to protect the test-subject pattern lines 2 and to prevent a probe in contact with the pad Pin from being broken.

The lead-out lines 35 extend in the Y direction and are provided between the lead-out line 32 and the lead-out line 33. The lead-out lines 35 electrically connect the lead-out line 32 and the lead-out line 33 together. The width of the lead-out lines 35 is larger than the widths of the test-subject lines 10 and 20. The width of the lead-out lines 35 may be the same as the widths of the lead-out lines 31 to 33.

The length of the lead-out lines 35 in the Y direction, that is, the distance between the lead-out line 33 and the lead-out line 32 is preferably set to be about10 μm to about 20 μm to space the lead-out line 33 and the lead-out line 32 apart from each other. This is for preventing the cause of the breakage of the lead-out line 34 functioning as the fuse due to the flow of the high current, from affecting the lead-out line 32.

For the lead-out lines 31 to 35, for example, a conductive material such as copper, tungsten, or aluminum is used. The test-subject lines 10 and 20, and the lead-out lines 31 to 35 may be provided by processing a conductor layer (e.g., a metal layer) in the same layer. As a result, only replacing one mask pattern with another mask pattern in a lithography technique suffices to form the test-subject lines 10 and 20, and the lead-out lines 31 to 35. Thus, the test-subject lines 10 and 20, and the lead-out lines 31 to 35 can be formed in one conductor layer, with no additional step.

The pad Pout is electrically connected to the lead-out line 31 via the contact C1. The pad Pe is electrically connected to the lead-out line 32 via the contact C2. The pad Pin is electrically connected to the lead-out lines 33 and 34 via the contact C3. For the pads Pin, Pout, and Pe, for example, a conductive material such as copper, tungsten, or aluminum is used.

The pads Pin, Pout, and Pe are provided in a conductor layer provided above the test-subject lines 10 and 20, and the lead-out lines 31 to 35. Between the conductor layer of the test-subject lines 10 and 20, and the lead-out lines 31 to 35 and the conductor layer of the pads Pin, Pout, and Pe, an insulating layer (not illustrated) is provided. The insulating layer is penetrated by the contacts C1 to C3. The contact C1 is provided between the lead-out line 31 and the pad Pout and electrically connects the lead-out line 31 and the pad Pout together. The contact C2 is provided between the lead-out line 32 and the pad Pe and electrically connects the lead-out line 32 and the pad Pe together. The contact C3 is provided between the lead-out line 33 and the pad Pin and electrically connects the lead-out line 33 and the pad Pin together. The pads Pin, Pout, and Pe may each overlap the test-subject lines 10 and 20 or the lead-out lines 31 to 35 in a plan view from the Z direction. Thus, the area of the pattern necessary for a breakdown test can be decreased.

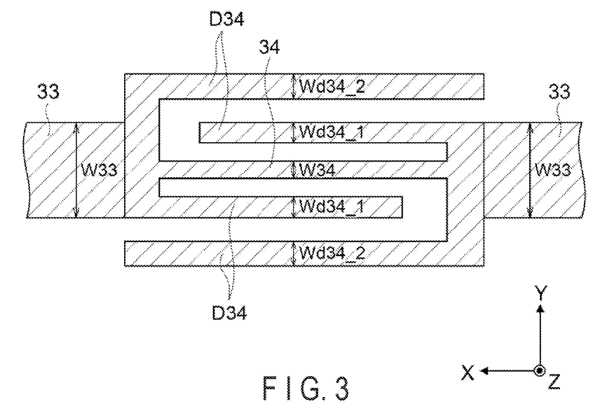

FIG. 3 is a plan view illustrating a configuration example of the lead-out line 34. A width W34 of the lead-out line 34 functioning as a fuse is equal to or smaller than the widths of the test-subject lines 10 and 20 and is 1/3 or less than a width W33 of the lead-out line 33. A lower limit of the width W34 of the lead-out line 34 may be a minimum width that can be formed by a lithography technique and an etching technique. The length of the lead-out line 34 is set to be a length that can be formed by a lithography technique and an etching technique.

In order to form such a thin lead-out line 34, dummy lines D34 are provided. The dummy lines D34 extends substantially in parallel to the lead-out line 34, in the X direction. Widths Wd34_1 and Wd34_2 of the dummy lines D34 are made larger than the width W34 of the lead-out line 34 in a stepwise manner with a distance from the lead-out line 34. That is, the width Wd34_1 is larger than the width W34 to a certain extent, and the width Wd34_2 is larger than the width Wd34_1 to a certain extent. By disposing such dummy lines D34 near the lead-out line 34, the width of lead-out line 34 can be formed to be the desired width W34 stably by using a lithography technique and an etching technique or a chemical mechanical polishing (CMP) method. For example, in the case where the lead-out line 34 is formed in an insulating layer not illustrated by a damascene process, a material of the lead-out line 34 is embedded in a trench in the insulating layer, and then the material of the lead-out line 34 is polished by the CMP method.

At this time, if no dummy lines D34 are provided near the thin lead-out line 34, the insulating layer near the lead-out line 34 may be excessively polished due to a difference in hardness between the lead-out line 34 and the insulating layer. In another case, the lead-out line 34 may be excessively polished, thus failing to be formed with a thickness as designed.

In contrast, in the present embodiment, the dummy lines D34 provided near the lead-out line 34 prevent the insulating layer near the lead-out line 34 from being excessively polished in the polishing by the CMP method. Thus, the lead-out line 34 can be formed with the thickness as designed.

Next, the breakdown test step will be described.

The semiconductor wafer 1 according to the present embodiment is mounted on a semiconductor tester not illustrated. Probes of a probe card come into contact with the pads Pout and Pin in FIG. 2. To the pad Pout, for example, a ground voltage is applied as a reference voltage. To the pad Pin, for example, a high-level voltage higher than the reference voltage is applied. The high-level voltage is stepped up or swept so as to gradually rise from the reference voltage. Thus, the voltage of the test-subject lines 20 rises while the voltage of the test-subject lines 10 is maintained at the reference voltage. Since the test-subject lines 10 and the test-subject lines 20 are electrically isolated by the test-subject insulating film 15, an electric field applied to the test-subject insulating film 15 is strengthened as the voltage of the test-subject lines 20 rises.

When a voltage difference between the test-subject lines 10 and the test-subject lines 20 exceeds the breakdown voltage of the test-subject insulating film 15, a breakdown occurs in the test-subject insulating film 15, and a relatively high current flows between one or more of the test-subject lines 10 and one or more of the test-subject lines 20.

At this time, since the lead-out line 34 has a smaller width than the other lead-out lines 31 to 33 and 35 and the test-subject lines 10 and 20, the lead-out line 34 functions as a fuse, thus melting to break. This electrically isolates the lead-out line 33 on the contact C3 side and the lead-out line 31 from each other. That is, the pad Pin and the pad Pout are electrically isolated from each other. As a result, after the breakage of the lead-out line 34 due to the breakdown of the test-subject insulating film 15, almost no current flows between the test-subject lines 10 and the test-subject lines 20. This can prevent any further damage to the test-subject pattern lines 2. This can also prevent damage to the probes in contact with the pads Pin and Pout.

Next, an evaluation step after the breakdown test will be described.

After the breakdown test, in which the lead-out line 34 has broken, the pad Pin is not electrically connected to the test-subject pattern lines 2 and cannot be used in evaluation.

Hence, in the present embodiment, the pad Pe is used in the evaluation step. The pad Pe is electrically connected to the test-subject lines 20 via the contact C2 and the lead-out line 32. Therefore, the pad Pe can be used to evaluate the test-subject pattern lines 2 after the breakdown test.

For example, the voltage of the pad Pe is raised from the reference voltage while the voltage of the pad Pout is maintained at the reference voltage. After the breakdown test, this enables the measurement of the value of current flowing between the test-subject lines 10 and the test-subject lines 20 and enables the location of the breakdown in the test-subject pattern lines 2 to be spotted. In this manner, the test-subject pattern lines 2 can be evaluated by using the pad Pe, which is different from the pad Pin used in the test step.

As described above, the semiconductor wafer 1 according to the present embodiment is provided with the lead-out line 34, which has a smaller width than the lead-out lines 31 to 33 and 35 and the test-subject lines 10 and 20, as a part of the lead-out line 33. This makes the lead-out line 34 function as a fuse in the test step, making it possible to protect the test-subject pattern lines 2 after the breakdown of the test-subject insulating film 15. It is also possible to protect the probes in contact with the pads Pin and Pout.

In the semiconductor wafer 1 according to the present embodiment, the lead-out lines 32 and 33 to which the high-level voltage is to be applied are connected to the test-subject lines 20. In accordance with this configuration, the pads Pin and Pe are provided on the test-subject lines 20 side. Therefore, even when the lead-out line 34 breaks to electrically isolate the pad Pin from the test-subject lines 20 in the breakdown test, the test-subject pattern lines 2 can be evaluated using the pad Pe after the breakdown test.

As seen from the above, according to the present embodiment, it is possible to prevent damage to the probes and damage to the test-subject pattern lines 2 in the test step, and it is possible to accurately evaluate the test-subject pattern lines 2 after the test step.

In the above-described embodiment, the high-level voltage is applied to the pad Pin in the breakdown test step. However, a low-level voltage may be applied to the pad Pin. In this case, the low-level voltage applied to the pad Pin is stepped down or swept so as to gradually fall from the reference voltage. Thus, the voltage of the test-subject lines 20 falls while the voltage of the test-subject lines 10 is maintained at the reference voltage. In this manner, an electric field that is the inverse of that in the first embodiment may be applied to the test-subject insulating film 15 in the breakdown test step. In this case, in the evaluation step, the voltage of the pad Pe is caused to fall from the reference voltage. After the breakdown test, this enables the measurement of the value of current flowing between the test-subject lines 10 and the test-subject lines 20 and enables the location of the breakdown in the test-subject pattern lines 2 to be spotted. As seen from the above, the voltage applied to the pads Pin and Pe may be negative with respect to the reference voltage.

### Second Embodiment

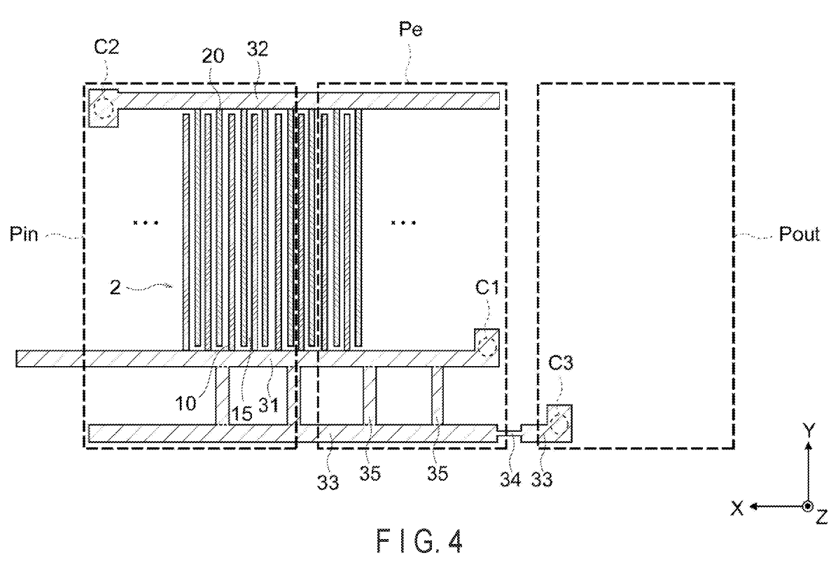

FIG. 4 is a plan view illustrating a configuration example of test-subject pattern lines and the vicinity thereof according to a second embodiment. In the second embodiment, the lead-out lines 33 to 35 are provided in the lead-out line 31 to which the reference voltage is to be applied.

The lead-out line 33 extends in the X direction and is electrically connected to the lead-out line 31 via the lead-out lines 35. Therefore, the lead-out line 33 is electrically connected to all of the plurality of test-subject lines 10 via the lead-out lines 31 and 35. The lead-out line 33 is connected to the contact C3 at one end of the lead-out line 33. Via the contact C3, the lead-out line 33 is electrically connected to the pad Pout above (in the +Z direction) the lead-out line 33. The width of the lead-out line 33 may be the same as in the first embodiment.

The configuration of the lead-out line 34 may be the same as in the first embodiment.

The lead-out lines 35 extend in the Y direction and are provided between the lead-out line 31 and the lead-out line 33. The lead-out lines 35 electrically connect the lead-out line 31 and the lead-out line 33 together. The width of the lead-out lines 35 may be the same as in the first embodiment.

The pad Pout is electrically connected to the lead-out lines 33 and 34 via the contact C3. The pad Pe is electrically connected to the lead-out line 31 via the contact C1. The pad Pin is electrically connected to the lead-out line 32 via the contact C2.

The rest of the configuration in the second embodiment may be the same as that in the first embodiment.

Next, a breakdown test step in the second embodiment will be described.

Probes of a probe card come into contact with the pads Pout and Pin in FIG. 2. To the pad Pout, for example, a ground voltage is applied as a reference voltage. To the pad Pin, for example, a high-level voltage higher than the reference voltage is applied. The high-level voltage is stepped up or swept so as to gradually rise from the reference voltage. Thus, the voltage of the test-subject lines 20 rises while the voltage of the test-subject lines 10 is maintained at the reference voltage.

When a voltage difference between the test-subject lines 10 and the test-subject lines 20 exceeds the breakdown voltage of the test-subject insulating film 15, a breakdown occurs in the test-subject insulating film 15, and a relatively high current flows between one or more of the test-subject lines 10 and one or more of the test-subject lines 20.

At this time, the lead-out line 34 functions as a fuse, thus melting to break. This electrically isolates the lead-out line 33 on the contact C3 side and the lead-out line 31 from each other. This can prevent any further damage to the test-subject pattern lines 2. This can also prevent damage to the probes in contact with the pads Pin and Pout.

Next, an evaluation step after the breakdown test will be described.

After the breakdown test, in which the lead-out line 34 has broken, the pad Pout is not electrically connected to the test-subject pattern lines 2 and cannot be used in evaluation.

Hence, the pad Pe is used in the evaluation step. The pad Pe is electrically connected to the test-subject lines 20 via the contact C1 and the lead-out line 31. Therefore, the pad Pe can be used to evaluate the test-subject pattern lines 2 after the breakdown test.

For example, the voltage of the pad Pin is raised from the reference voltage while the voltage of the pad Pe is maintained at the reference voltage. After the breakdown test, this enables the measurement of the value of current flowing between the test-subject lines 10 and the test-subject lines 20 and enables the location of the breakdown in the test-subject pattern lines 2 to be spotted. In this manner, the test-subject pattern lines 2 can be evaluated by using the pad Pe, which is different from the pad Pin used in the test step.

As seen from the above, the provision of the lead-out lines 33 to 35 on the lead-out line 31 side can also produce the effects of the present embodiment.

Note that, in the second embodiment, the low-level voltage may be applied to the pad Pin in the breakdown test step as in the first embodiment.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor wafer comprising:
test-subject pattern lines including a first test-subject insulating film and further including first test-subject lines and second test-subject lines that are alternately disposed on the first test-subject insulating film to be electrically insulated from each other;
a first lead-out line that is electrically connected to the first test-subject lines, a width of the first lead-out line being larger than widths of the first and second test-subject lines;
a second lead-out line that is electrically connected to the second test-subject lines, a width of the second lead-out line being larger than the widths of the first and second test-subject lines; and
a third lead-out line that is electrically connected to the second lead-out line, the third lead-out line including first and second sections having a width that is larger than the widths of the first and second test-subject lines, and an intermediate section between the first and second sections, the intermediate section having a width that is smaller than the widths of the first and second sections.

2. The semiconductor wafer of claim 1, wherein the width of the intermediate section is 1/3 or less than the width of the first and second sections.

3. The semiconductor wafer of claim 1, wherein the width of the intermediate section is smaller than the width of the first test-subject lines or the width of the second test-subject lines.

4. The semiconductor wafer of claim 1, further comprising:
a first pad connected to the first lead-out line;
a second pad connected to the second lead-out line; and
a third pad connected to the third lead-out line.

5. The semiconductor wafer of claim 4, wherein the test-subject pattern lines extend in a first direction and the first, second, and third lead-out lines extend in a second direction that crosses the first direction.

6. The semiconductor wafer of claim 5, further comprising:
a first contact extending between the first lead-out line and the first pad in a third direction that is perpendicular to the first and second directions;
a second contact extending between the second lead-out line and the second pad in the third direction; and
a third contact extending between the third lead-out line and the third pad in the third direction.

7. The semiconductor wafer of claim 5, further comprising:
a plurality of fourth lead-out lines extending in the first direction between the second lead-out line and the third lead-out line, spaced apart in the second direction, and each having a width that is larger than the widths of the first and second test-subject lines.

8. The semiconductor wafer of claim 1, further comprising:
first and second dummy lead-out lines, each having a closed, first end connected to the first section and an open, second end that is opposite to the first end thereof, and third and fourth dummy lead-out lines, each having a closed, first end connected to the second section and an open, second end that is opposite to the first end thereof.

9. The semiconductor wafer of claim 8, wherein
the intermediate section is between the first and third dummy lead-out lines, and
the widths of the first, second, third, and fourth dummy lead-out lines are each smaller than the width of the first and second sections but larger than the width of the intermediate section.

10. The semiconductor wafer of claim 9, wherein
the first dummy lead-out line is between the intermediation section and the fourth dummy lead-out line, and the third dummy lead-out line is between the intermediation section and the second dummy lead-out line, and the
the widths of the first and third dummy lead-out lines are each smaller than the widths of the second and fourth dummy lead-out lines.

11. A method of testing a semiconductor wafer comprising:
test-subject pattern lines including a first test-subject insulating film and further including first test-subject lines and second test-subject lines that are alternately disposed on the first test-subject insulating film to be electrically insulated from each other;
a first lead-out line that is electrically connected to the first test-subject lines, a width of the first lead-out line being larger than widths of the first and second test-subject lines;
a second lead-out line that is electrically connected to the second test-subject lines, a width of the second lead-out line being larger than the widths of the first and second test-subject lines;
a third lead-out line that is electrically connected to the second lead-out line, the third lead-out line including first and second sections having a width that is larger than the widths of the first and second test-subject lines, and an intermediate section between the first and second sections, the intermediate section having a width that is smaller than the widths of the first and second sections;
a first pad connected to the first lead-out line;
a second pad connected to the second lead-out line; and
a third pad connected to the third lead-out line, wherein
said method comprises:
applying a reference voltage to the first pad, and
applying a voltage higher or lower than the reference voltage to the third pad.

12. The method of claim 11, wherein the voltage higher than the reference voltage is applied to the third pad and the voltage applied to the third pad is gradually increased until the intermediate section melts and the first and second sections become electrically isolated from each other.

13. The method of claim 12, further comprising:
after the intermediate section melts, applying the reference voltage to the first pad, applying a voltage higher than the reference voltage to the second pad, and measuring a current flow between the first test-subject lines and the second test-subject lines.

14. The method of claim 11, wherein the voltage lower than the reference voltage is applied to the third pad and the voltage applied to the third pad is gradually decreased until the intermediate section melts and the first and second sections become electrically isolated from each other.

15. The method of claim 14, further comprising:
after the intermediate section melts, applying the reference voltage to the first pad, applying a voltage lower than the reference voltage to the second pad, and measuring a current flow between the first test-subject lines and the second test-subject lines.

16. A method of testing a semiconductor wafer comprising:
test-subject pattern lines including a first test-subject insulating film and further including first test-subject lines and second test-subject lines that are alternately disposed on the first test-subject insulating film to be electrically insulated from each other;
a first lead-out line that is electrically connected to the first test-subject lines, a width of the first lead-out line being larger than widths of the first and second test-subject lines;
a second lead-out line that is electrically connected to the second test-subject lines, a width of the second lead-out line being larger than the widths of the first and second test-subject lines;
a third lead-out line that is electrically connected to the second lead-out line, the third lead-out line including first and second sections having a width that is larger than the widths of the first and second test-subject lines, and an intermediate section between the first and second sections, the intermediate section having a width that is smaller than the widths of the first and second sections;
a first pad connected to the first lead-out line;
a second pad connected to the second lead-out line; and
a third pad connected to the third lead-out line, wherein
said method comprises:
applying a reference voltage to the third pad, and
applying a voltage higher or lower than the reference voltage to the first pad.

17. The method of claim 16, wherein the voltage higher than the reference voltage is applied to the first pad and the voltage applied to the first pad is gradually increased until the intermediate section melts and the first and second sections become electrically isolated from each other.

18. The method of claim 17, further comprising:
after the intermediate section melts, applying the reference voltage to the third pad, applying a voltage higher than the reference voltage to the second pad, and measuring a current flow between the first test-subject lines and the second test-subject lines.

19. The method of claim 16, wherein the voltage lower than the reference voltage is applied to the first pad and the voltage applied to the first pad is gradually decreased until the intermediate section melts and the first and second sections become electrically isolated from each other.

20. The method of claim 19, further comprising:
after the intermediate section melts, applying the reference voltage to the third pad, applying a voltage lower than the reference voltage to the second pad, and measuring a current flow between the first test-subject lines and the second test-subject lines.
